(19) United States
(12) Patent Application Publication
(10) Pub. No.: US 2011/0161581 A1
(43) Pub. Date: Jun. 30, 2011

(54) SEMICONDUCTOR CIRCUIT APPARATUS

(75) Inventor: Sang Hoon SHIN, Gyeonggi-do (KR)

(73) Assignee: HYNIX SEMICONDUCTOR INC., Gyeonggi-do (KR)

(21) Appl. No.: 12/833,066

(22) Filed: Jul. 9, 2010

(30) Foreign Application Priority Data
Dec. 24, 2009 (KR) 10-2009-0130726

(51) Int. Cl. G06F 13/28; G11C 8/04

(52) U.S. Cl. 711/109; 365/230.08; 711/E12.001; 365/240; 365/233.1

(57) ABSTRACT

A semiconductor circuit apparatus having a commonly shared control unit that coordinates reading and writing timed activities in two ranked subcircuits is presented. The semiconductor circuit includes: first and second ranks; and a rank control block shared by the first and second ranks and configured to provide a column-related command and an address to one of the first and second ranks in response to a chip select signal for selecting the first or second rank.

### CROSS-REFERENCES TO RELATED APPLICATION

The present application claims priority under 35 U.S.C. §119(a) to Korean application number 10-2009-0130726, filed on Dec. 24, 2009, in the Korean Intellectual Property Office, which is incorporated herein by reference in its entirety as set forth in full.

### BACKGROUND

1. Technical Field

The present invention relates to a semiconductor circuit apparatus, and more particularly, to a semiconductor circuit apparatus which controls ranks.

2. Related Art

In general, a rank in a semiconductor circuit apparatus refers to a unit memory chip which is controlled by one chip select signal and has an independent function. Depending on the configuration of the semiconductor circuit apparatus, one or more ranks may be provided. Here, a signal for activating ranks may be a chip select signal CS or chip enable signal CE. Each of the ranks is installed in such a manner that a unit memory chip having a plurality of semiconductor memory cells integrated therein is attached on a printed circuit board (PCB) and connected to a panel or the like through a plurality of contact terminals.

Meanwhile, according to an inter-rank timing regulation, that is, a timing spec defined to satisfy a read or write mode between different ranks, tWTR is 1tCK. In this case, the respective ranks include an individual column command control unit and an individual address control unit such that when address information is provided to the corresponding rank, information of the rank does not collided with that of another rank.

In the write mode, the address control unit should apply a write latency to provide address information to the rank. In this case, such a write latency delays the address through a plurality of shift registers. Therefore, when the address control unit is provided for each rank, it may degrade area efficiency of the semiconductor circuit apparatus.

### SUMMARY

A semiconductor circuit apparatus which controls a plurality of ranks is described herein.

In one embodiment of the present invention, a semiconductor circuit apparatus includes: first and second ranks; and a rank control block shared by the first and second ranks and configured to provide a column-related command and an address to one of the first and second ranks in response to a chip select signal for selecting the first or second rank.

In another embodiment of the present invention, a semiconductor circuit apparatus includes: first and second ranks; a command control unit configured to provide a column-related activation signal for each rank and read and write information signals of the corresponding rank in response to an chip signal for selecting the first or second rank; and an address control unit configured to latch the address in response to read and write combined information signals irrelevant to rank information.

### BRIEF DESCRIPTION OF THE DRAWINGS

Features, aspects, and embodiments are described in conjunction with the attached drawings, in which:

FIG. 1 is a block diagram of a semiconductor circuit apparatus according to one embodiment;

FIG. 2 is a block diagram of a rank control unit of FIG. 1;

FIG. 3 is a block diagram of a command control block of FIG. 2;

FIG. 4 is a block diagram of an address control block of FIG. 2;

FIG. 5 is a circuit diagram of a first address latch of FIG. 4;

FIG. 6 is a circuit diagram of a second address latch of FIG. 4;

FIG. 7 is a circuit diagram of a shift register of FIG. 4;

FIG. 8 is a circuit diagram of a first address supply unit of FIG. 4; and

FIG. 9 is a voltage waveform diagram showing the operation of the semiconductor circuit apparatus of FIG. 1.

### DETAILED DESCRIPTION

Hereinafter, a semiconductor circuit apparatus according to the present invention will be described below with reference to the accompanying drawings through preferred embodiments.

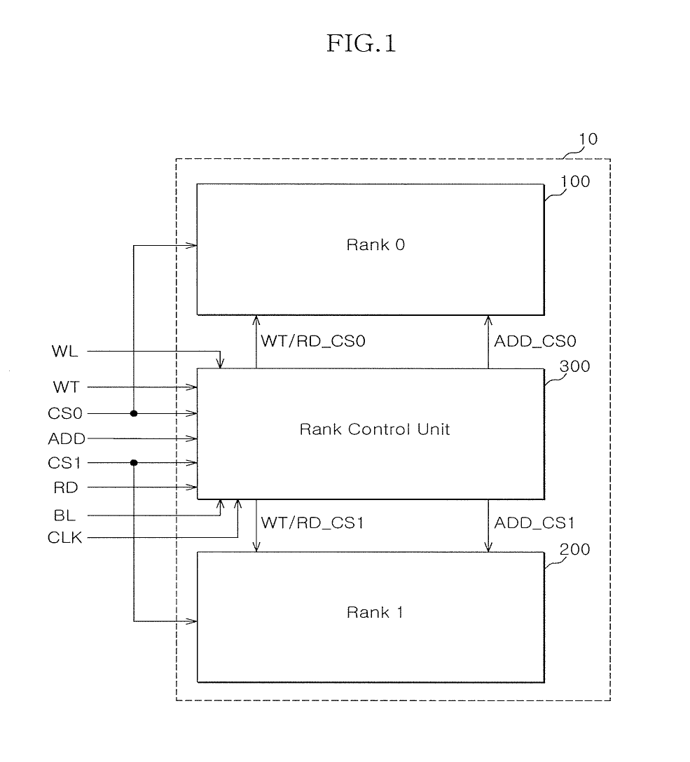

FIG. 1 is a block diagram of a semiconductor circuit apparatus 10 according to one embodiment.

Referring to FIG. 1, the semiconductor circuit apparatus 10 according to the embodiment includes a first rank 100, a second rank 200, and a rank control unit 300.

The first rank 100 is a memory area which is activated by a first chip select signal CS0. The second rank 200 is a memory area which is activated by a second chip select signal CS1. The first and second rank 100 and 200 may be referred to as first and second chips, respectively. In the semiconductor circuit apparatus configured in such a dual rank mode for supporting two ranks, the first and second ranks 100 and 200 may be independently driven by the respective individual first or second chip select signals CS0 and CS1.

The rank control unit 300 latches column-related commands WT and RD and an address ADD and provides the latched column-related commands and address to the corresponding ranks 100 and 200 in accordance with the activated chip select signals CS0 and CS1.

The rank control unit 300 receives the column-related commands WT and RD, the first and second chip select signals CS0 and CS1, the address ADD, a clock signal CLK, and a write latency WL, and a burst length BL, and provides a first rank column command signal WT/RD_CS0 and a first rank address signal ADD_CS0 to the first rank 100 or a second rank column command signal WT/RD_CS1 and a second rank address signal ADD_CS1 to the second rank 200.

That is, the rank control unit 300 according to this embodiment is a shared circuit unit configured to control the column-related commands WT and RD and the address of the respective ranks 100 and 200. More specifically, the rank control unit 300 receives the column-related commands WT and RD, and selectively provides the column-related commands WT and RD to the corresponding ranks 100 and 200 in accordance with the activated chip select signals CS0 and CS1. Furthermore, the rank control unit 300 according to this embodiment may selectively provide an address signal (not shown) to the corresponding ranks 100 and 200, the address signal being delayed by applying a necessary latency while latching the address ADD. This is different from the conventional semiconductor circuit apparatus including the address control unit and the column command control unit which are provided for each rank. The ranks are controlled by the shared rank control unit 300 in the semiconductor circuit apparatus 10 according to the embodiment. Therefore, it is possible to control the independent drive of each rank and improve the area efficiency of the semiconductor circuit apparatus.

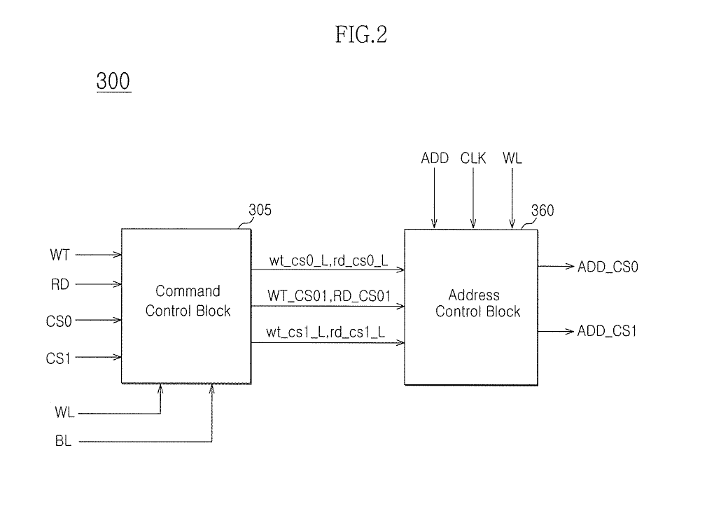

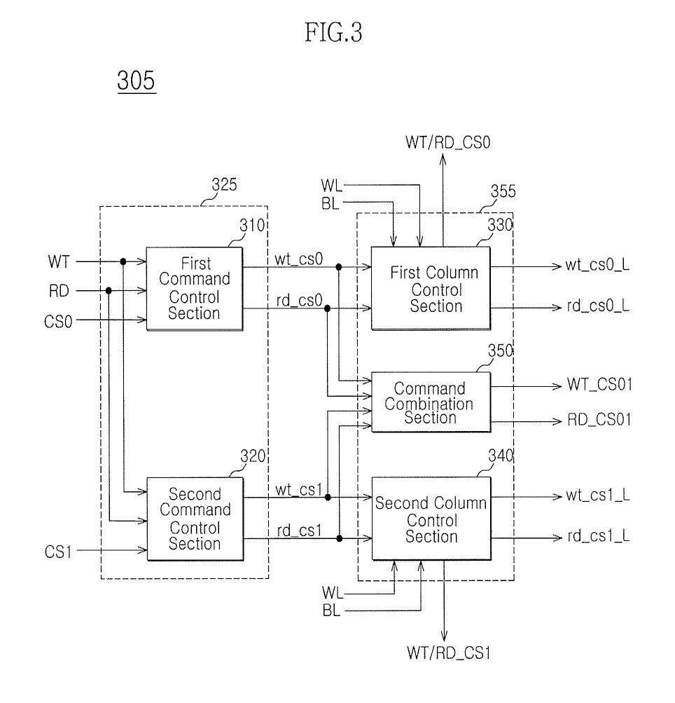

FIG. 2 is a block diagram of the rank control unit 300 of FIG. 1. FIG. 3 is a block diagram of a command control block 305 of FIG. 2.

Referring to FIGS. 2 and 3, the rank control unit 300 includes a command control block 305 and an address control block 360.

The command control block 305 is configured to provide read and write signals for the corresponding rank and read and write signals without discrimination between the ranks, in response to the first and second chip select signals CS0 and CS1, the column-related commands WT and RD, the write latency WL, and the burst length BL. More specifically, when the column-related commands WT and RD are inputted, the command control block 305 provides a first write information signal wt_cs0_L, a first read information signal rd_cs0_L, a second write information signal wt_cs1_L, a second read information signal rd_cs1_L, a write combined information signal WT_CS01, and a read combined information signal RD_CS01, in response to the corresponding chip select signals CS0 and CS1.

The command control block 305 includes a command reception unit 325 and a column command control unit 355.

The command reception unit 325 is configured to receive the column-related commands WT and RD and the first and second chip select signals CS0 and CS1 and configured to provide a first rank write signal wt_cs0, a first rank read signal rd_cs0, a second rank write signal wt_cs1, and a second rank read signal rd_cs1.

The command reception unit 325 includes a first command control section 310 and a second command control section 320.

The first command control section 310 provides the first rank write signal wt_cs0 and the first rank read signal rd_cs0 in response to the column-related commands WT and RD and the first chip select signal CS0. Then, when the first chip select signal CS0 and the write command WT of the column-related commands WT and RD are activated, the first command control section 310 provides the activated first rank write signal wt_cs0. Furthermore, when the first chip select signal CS0 and the read command RD are activated, the first command control section 310 provides the first rank read signal rd_cs0.

The second command control section 320 provides the second rank write signal wt_cs1 and the second rank read signal rd_cs1 in response to the column-related commands WT and RD and the second chip select signal CS1. Similar to the first command control section 310, when the second chip select signal CS1 and the write command WT of the column-related commands WT and RD are activated, the second command control section 320 provides the activated second rank write signal wt_cs1. Furthermore, when the second chip select signal CS1 and the read command RD are activated, the second command control section 320 provides the second rank read signal rd_cs1.

That is, the column-related commands WT and RD are provided to both of the first and second command control sections 310 and 320. At this time, the column-related signals activated by the corresponding command control section may be provided in response to the respective activated chip select signals CS0 and CS1.

The column command control unit 355 receives the first rank write signal wt_cs0, the first rank read signal rd_cs0, the second rank write signal wt_cs1, the second rank read signal rd_cs1, the burst length BL, and the write latency WL, and provides a first column-related activation signal WT/RD_CS0, a second column-related activation signal WT/RD_CS1, a write combined information signal WT_CS01, a read combined information signal RD_CS01, a first write information signal wt_cs0_L, a first read information signal rd_cs0_L, a second write information signal wt_cs1_L, and a second read information signal rd_cs1_L. That is, the column command control unit 355 receives the activated column-related signal, determines whether the received column-related signal is a column-related signal for the first rank or the second rank, and provides the column-related activation signal to the corresponding rank. Furthermore, the column command control unit 355 combines the respective column commands to provide the write combined information signal WT_CS01 and the read combined information signal RD_CS01 to the address control block 360. The write combined information signal WT_CS01 and the read combined information signal RD_CS01 inform whether the combined information is write information or read information irrelevant to the ranks.

The column command control unit 355 includes a first column control section 330, a second column control section 340, and a command combination section 350.

The first column control section 330 receives the first rank write signal wt_cs0 and the first rank read signal rd_cs0, and provides the first column-related activation signal WT/RD_CS0 to the first rank 100. The first column-related activation signal WT/RD_CS0 is a main signal which is used to activate column-related signals. Accordingly, the first rank 100 activates the column-related signals in response to the first column-related activation signal WT/RD_CS0. Furthermore, the first column control section 330 receives the first rank write signal wt_cs0, and provides the first write information signal wt_cs0_L to the address control block 360 in the write mode, the first write information signal wt_cs0_L being delayed by the write latency WT and the burst length BL. That is, the first write information signal wt_cs0_L is a signal which is used to control latching an address related to a timing at which a write control operation is to be substantially performed in an internal circuit, in response to a write command provided from outside. Therefore, the first write information signal wt_cs0_L is a signal which has timing information for fetching an address signal required when the write operation of the internal circuit is performed, after data is inputted by the burst length BL after a predetermined write latency WL in response to the external write command. Meanwhile, since a latency is not required in the read mode, the first column control section 330 provides the first rank read signal rd_cs0 as the first read information signal rd_cs0_L without delay.

Similar to the first column control section 330, the second column control section 340 receives the second rank write signal wt_cs1 and the second rank read signal rd_cs1, and provides a second column-related activation signal WT/RD_CS1 to the second rank 200. The second column-related activation signal WT/RD_CS1 is a main signal which is used to activate the column-related signals. Accordingly, the second column control section 340 receives the second rank write signal wt_cs1, and provides a second write information signal wt_cs1_L to the address control block 360 in the write mode, the second write information signal wt_cs1_L being delayed by the write latency WL and the burst length BL. In the read mode, however, the second column control section 340 provides the second rank read signal rd_cs1 as the second read information signal rd_cs1_L without delay.

The command combination unit 350 is configured to combine the respective column-related commands and provide the write combined information signal WT_CS01 and the read combined information signal RD_CS01 to the address control block 360. The write combined information signal WT_CS01 and the read combined information signal RD_CS01 inform whether the combined information is write information or read information which is irrelevant to the ranks.

The address control block 360 receives the clock signal CLK, the write latency WL, the address ADD, the write combined information signal WT_CS01, the read combined information signal RD_CS01, and the read and write information signals relevant to the respective ranks, and provides a first rank address ADD_CS0 and a second rank address ADD_CS1.

The address control block 360 latches the address ADD provided from outside in response to the write combined information signal WT_CS01 and the read combined information signal RD_CS01, respectively. In the write mode, the address control block 360 applies the write latency to the address ADD and provides the address ADD to the corresponding rank in response to the activated information signal relevant to the rank. In the read mode, the address control block 360 provides the address ADD to the corresponding rank in response to the activated information signal relevant to the rank, without applying the latency.

According to the embodiment, the command control unit and the address command unit are not provided for each of the ranks, but rather one rank control unit is shared by the plurality of ranks. Therefore, it is possible to improve the area efficiency.

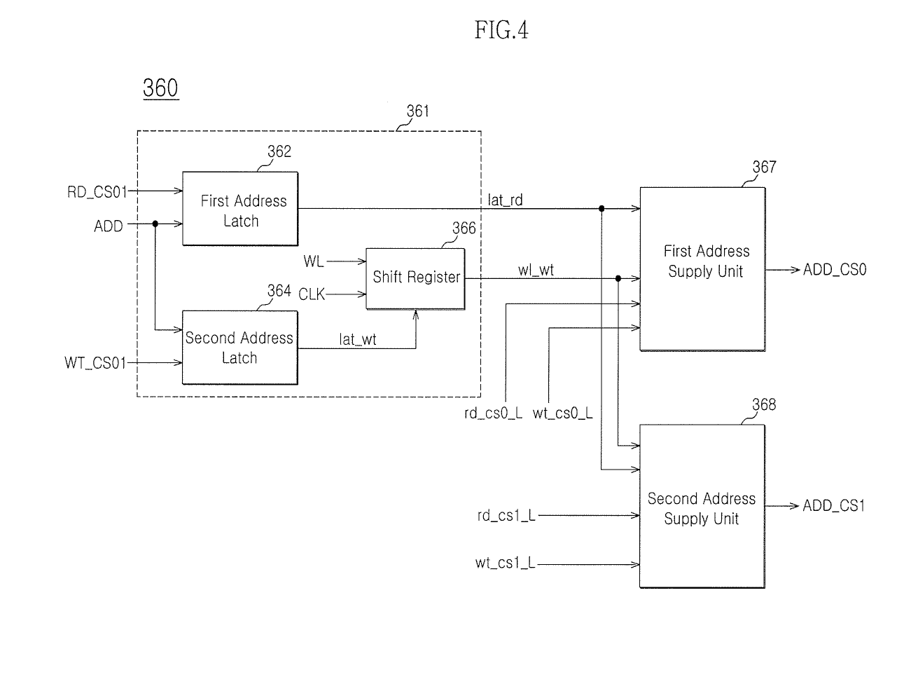

FIG. 4 is a block diagram of the address control block 360 of FIG. 2.

Referring to FIG. 4, the address control block 360 includes an address separation unit 361, a first address supply unit 367, and a second address supply unit 368.

The address separation unit 361 includes a first address latch 362, a second address latch 364, and a shift resistor 366.

The first address latch 362 receives the read combined information signal RD_CS01 and the address ADD to provide a read address lat_rd. That is, the first address latch 362 is an address latch for a read operation. Since a typical address latch is used as the first address latch 362, the detailed description thereof will be omitted.

The second address latch 364 receives the write combined information signal WT_CS01 and the address ADD to provide a write address lat_wt. That is, the second address latch 364 is an address latch for a write operation.

The shift register 366 receives the write latency WL, the clock signal CLK, and the write address lat_wt, and subsequently provides a delayed write address wl_wt. As described above, such a write operation is a synchronous command requiring a clock-based time regulation. In other words, the write operation of the semiconductor circuit apparatus starts in response to a write column-related signal which is generated while satisfying a predetermined time regulation required for an actual write operation. Then, the shift register 366 applies the write latency WL to delay the write address lat_wt. That is, the shift register 366 synchronizes the write address lat_wt with the clock CLK to delay the write address lat_wt by the corresponding write latency WL, and to provide the delayed write address wl_wt suitable for a timing required for the write operation. In particular, the shift register 366 according to the embodiment applies the latency and provides the commonly-delayed write address in the write mode, regardless of the ranks. Therefore, it is possible to improve the area efficiency. This will be described below in detail with reference to drawings.

The first address supply unit 367 receives a first write address control signal wt_cs0_L, a first read address control signal rd_cs0_L, the read address lat_rd, and the delayed write address wl_wt, and provides the first rank address ADD_CS0 to the first rank 100.

The second address supply unit 368 receives a second write address control signal wt_cs1_L, a second read address control signal rd_cs1_L, the read address lat_rd, and the delayed write address wl_wt, and provides the second rank address ADD_CS1 to the second rank 200.

When providing the latched address to the corresponding ranks, the first and second address supply units 367 and 368 provide the latched address information through different signal paths (ranks) such that the address information of one rank does not collide with that of the other rank.

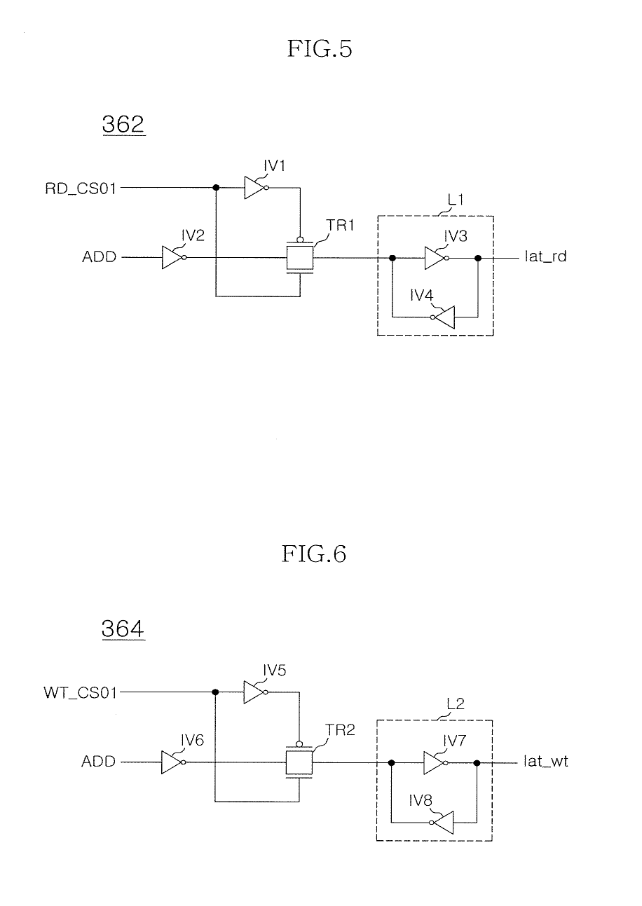

FIG. 5 is a circuit diagram of the first address latch 362 of FIG. 4. Referring to FIG. 5, the first address latch 362 includes a first transmission section TR1 and a first latch section L1. The first transmission section TR1 receives the address ADD in response to the read combined information signal RD_CS01.

The first latch section L1 latches the signal received from the first transmission section TR1, and includes third and fourth inverters IV3 and IV4.

The operation of the first address latch 362 will be described as follows. The first address latch 362 latches the address ADD in response to the read combined information signal RD_CS01. The read combined information RD_CS01 includes both of a first rank read command and a second rank read command. Then, when the read command for the first or second rank is provided, the first address latch 362 may latch the address ADD to provide the read address lat_rd. At this time, a separate latency for the read operation is not required.

FIG. 6 is a circuit diagram of the second address latch 364 of FIG. 4. Referring to FIG. 6, the second address latch 364 includes a second transmission section TR2 and a second latch section L2.

The second transmission section TR2 receives the address ADD in response to the write combined information signal WT_CS01.

The second latch section L2 latches the signal received from the second transmission section TR2, and includes seventh and eighth inverters IV7 and IV8.

The operation principle of the second address latch 364 is similar to that of the first address latch 364. Therefore, the descriptions thereof will be omitted to avoid the duplication. However, when the write command for the first or second rank is provided, the second address latch 364 may latch the address ADD to provide the write address lat_wt.

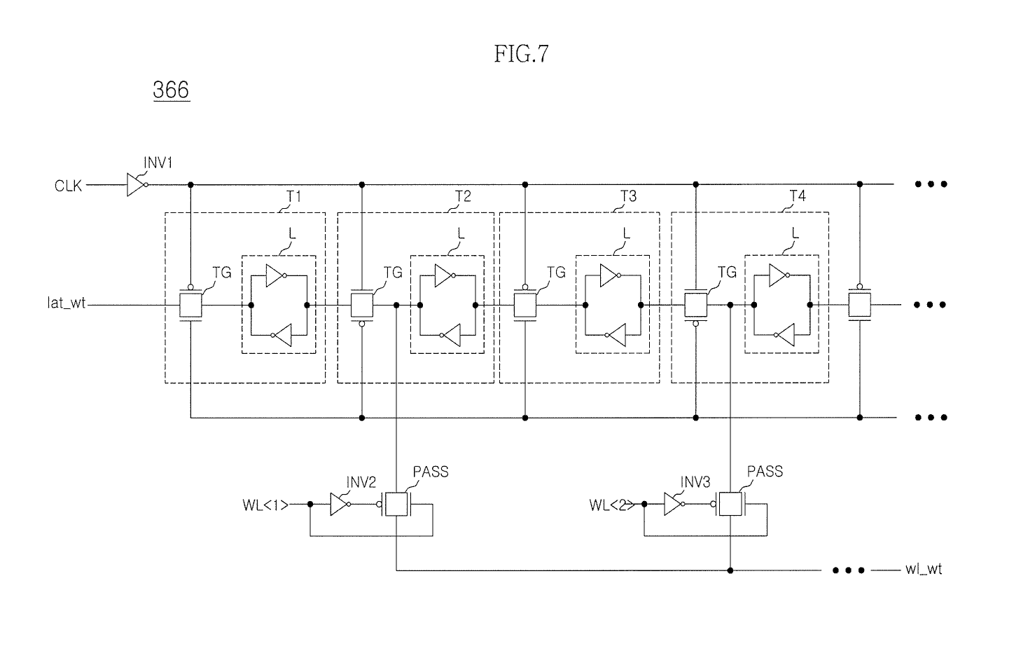

FIG. 7 is a circuit diagram of the shift register 366 of FIG. 4. Referring to FIG. 7, the shift register 366 includes a plurality of transmission sections T1, T2, T3 and t4. Each of the transmission sections T1, T2, T3 and T4 includes a transmission gate TG and a latch L.

The first transmission section T1 receives the write address lat_wt in synchronization with a rising edge of the clock signal CLK, and transmits the received write address lat_wt. The transmission gate TG is turned on in response to a high level of the clock signal CLK. The latch L latches the signal transmitted from the transmission gate TG.

The second transmission section T2 receives the signal from the first transmission section T1 in synchronization with a falling edge of the clock signal CLK, and transmits the received signal. The transmission gate TG is turned on in response to a low level of the clock signal CLK. The latch L latches the signal transmitted from the transmission gate TG.

As such, the respective transmission sections T1, T2, T3 and T4 are alternately turned on in response to the clock signal CLK. Then, when the first and third transmission sections T1 and T3 or the second and fourth transmission sections T2 and T4 are turned on to transmit a signal, each pair of a turned-on transmission section and a turned-off transmission section has a delay time corresponding to one clock period.

Meanwhile, the shift register 366 further includes pass gates PASS and inverters INV1, INV2, INV3, . . . . The pass gate PASS receives the write latency WL<1:4> through the inverters INV2, INV3, . . . .

The shift register 366 receives the write address lat_wt, delays the write address lat_wt by the write latency WL<1:4>, and provides the delayed write address wl_wt. Accordingly, it is possible to provide the delayed write address wl_wt to which the necessary write latency is applied, in the write mode.

The operation of the shift register 366 may be described more specifically as follows. When the write latency WL<1:4> is 1, the first write latency WL<1> is activated to a high level. Therefore, the pass gate PASS receiving the activated first write latency WL<1> is turned on to provide an output signal of the second transmission section T2 as the delayed write address wl_wt. That is, when a signal passes through the first and second transmission sections T1 and T2 or the third and fourth transmission sections T3 and T4, the delay time corresponding to one clock period is provided. Therefore, when the write latency is 1, an address signal delayed by one clock period may be provided.

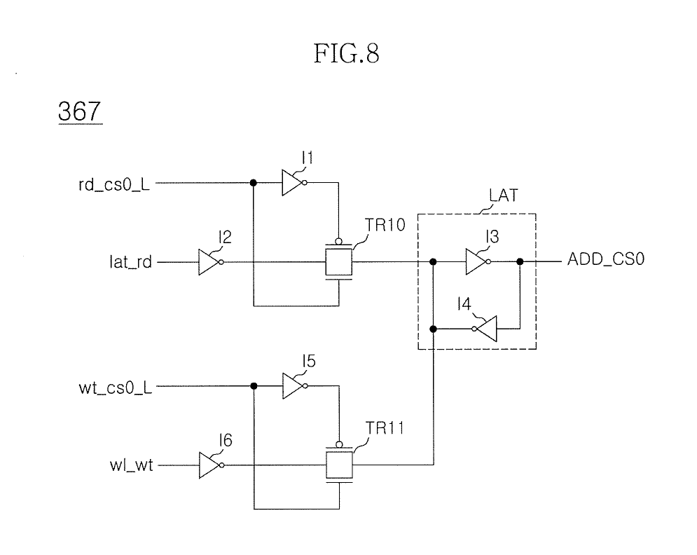

FIG. 8 is a circuit diagram of the first address supply unit 367 of FIG. 4.

Referring to FIG. 8, the first address supply unit 367 includes a first transmission section TR10, a second transmission section TR11, and a latch section LAT.

The first transmission section TR10 provides the read address lat_rd in response to the activated first read information signal rd_cs0_L.

The second transmission section TR11 provides the delayed write address wl_wt in response to the activated first write information signal wt_cs0_L. As described above, the delayed write address wl_wt is a signal to which the write latency WL is applied, and the first write information signal wt_cs0_L is a signal to which the write latency WL and the burst length BL are applied.

The latch section LAT includes third and fourth inverters 13 and 14. The latch section LAT receives the signal from the first and second transmission sections TR10 and TR11, and latches the received signal to provide as the first rank address ADD_CS0.

More specifically, the first address supply unit 367 provides the corresponding address as the first rank address ADD_CS0 in response to the read information and write information on the first rank. That is, the first address supply unit 367 provides the read address lat_rd as the first rank read ADD_CS0 in response to the activated first rank read address information signal rd_cs0_L. Similarly, when the first write information signal wt_cs0_L is activated, the first address supply unit 367 provides the write address lat_wt as the first rank address ADD_CS0.

The configuration and operation principle of the second address supply unit 368 are similar to those of the first address supply unit 367. Therefore, the descriptions thereof will be omitted.

According to the embodiment, when an address is provided to a corresponding rank while the address is latched by the combined read information or write information, the address is transmitted in response to the read information or write information of each rank. Accordingly, individual control units are not provided for each rank, but rather only one control unit is shared by all of the ranks, which makes it possible to realize improves in the area efficiency. A read or write command has a separated signal path such that different ranks can be selected. An address is latched regardless of the rank information and then controlled by read and write signals having rank information at a timing at which the read or write operation of the corresponding rank is performed. Therefore, the address can be provided only to the corresponding rank.

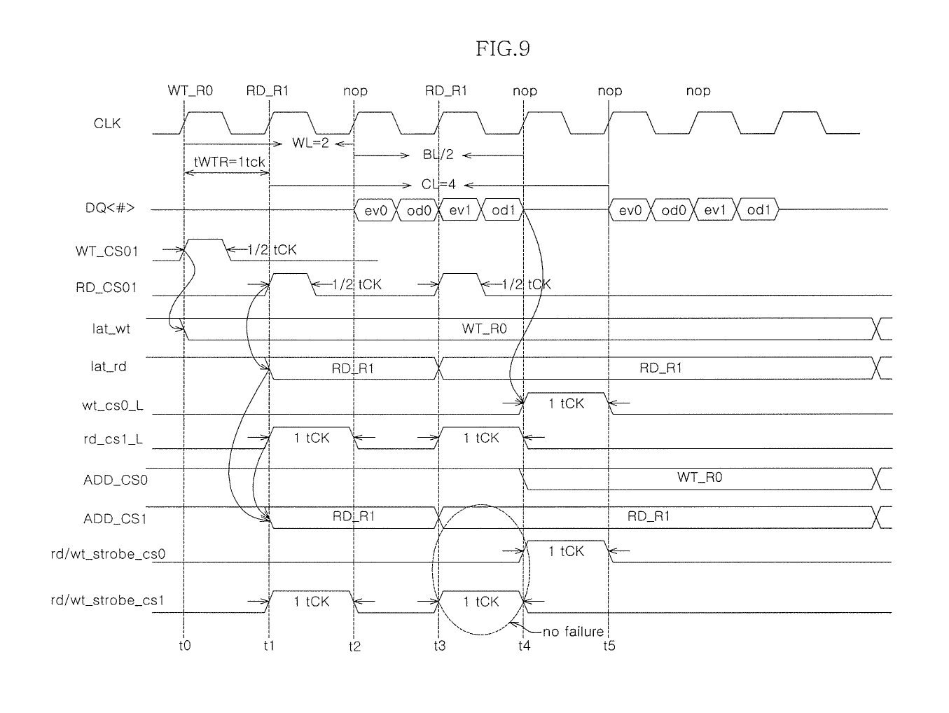

FIG. 9 is a voltage waveform diagram showing the operation of the semiconductor circuit apparatus of FIG. 1 according to the embodiment.

Referring to FIGS. 1 to 9, the operation of the semiconductor circuit apparatus according to the embodiment will be described.

At a time interval t0-t1, a command WT_R0 for performing the write mode of the first rank 100 is inputted.

In response to the command WT_R0, the write combined information signal WT_CS01 is activated. At this time, the pulse width of the write combined information signal WT_CS01 is ½ tCK. The address ADD is latched in response to the write combined information signal WT_CS01 to provide the write address lat_wt.

At a time interval t1-t2, a command RD_R1 for performing the read mode of the second rank 200 is inputted.

An inter-rank operation spec regulation is 1 tCK. Therefore, although the read command RD_R1 of the second rank 200 is inputted in one clock period after the write command WT_R0 of the first rank 100 is inputted, the operation can be performed.

In response to the read command, the read combined information signal RD_CS01 is activated. The address ADD is latched in response to the read combined information signal RD_CS01 to provide the read address lat_rd. Furthermore, since the latency is not necessary in the read mode, the read address lat_rd may be provided as the second rank address ADD_CS1 without delay.

Meanwhile, data is delayed by the write latency WL in response to the write command WT_R0 of the first rank 100, and then inputted from time t2.

At a time interval t3-t4, a command RD_R1 for performing the read mode of the second rank 200 is inputted. Since a column command input time in the same rank is defined as 2 tCK, the command input is suitable. Accordingly, the read combined information signal RD_CS01 is activated. In response to the read combined information signal RD_CS01, a newly-received address ADD is latched as the read address lat_rd. In response to the second rank read address signal rd_cs1_L to which latency does not need to be applied, the latched read address lat_rd is provided as the second rank address ADD_CS1.

At a time interval t4-t5, the first write information signal wt_cs0_L is delayed by the write latency WL and the burst length BL in response to the first rank write command WT_R0, and then activated. As described above, the first write information signal wt_cs0_L is activated after a predetermined time is delayed, so that the internal circuit operation of the first rank 100 is substantially performed at a timing at which the input of data is terminated in response to the write command.

Therefore, the latched write address lat_wt is provided as the first rank address signal ADD_CS0 in response to the activated first write information signal wt_cs0_L.

After time t5, the data is outputted after a predetermined CAS latency of the first read operation. Here, the CAS latency may be set to 4.

Signals capable of strobing the addresses of the respective ranks may be referred to as a first strobe signal rd/wt_strobe_cs0 and a second strobe signal rd/wt_strobe_cs1. The strobe signals may be activated in response to the first write address information signal wt_cs0_L and the second read address information signal rd_cs1_L, respectively. Therefore, it can be seen that an address signal fetched by the second strobe signal rd/wt_strobe_cs1 of the second read operation of the second rank does not collide with an address signal fetched by the first strobe signal rd/wt_strobe_cs0 of the write operation of the first rank (refer to a dotted circle of FIG. 9). In other words, although the rank control unit 300 is shared, it is possible to satisfy the inter-rank column operation spec regulation (1tCK).

According to the embodiment, the control unit shared by the plurality of ranks is provided, and a suitable latency is applied to selectively provide an address signal to the corresponding rank at a timing at which the internal circuit operation is substantially required in a state in which an address is latched at the same time when a column command is inputted. Therefore, while the inter-rank spec regulation is satisfied, the area efficiency can be improved.

While certain embodiments have been described above, it will be understood to those skilled in the art that the embodiments described are by way of example only. Accordingly, the semiconductor circuit apparatus described herein should not be limited based on the described embodiments. Rather, the semiconductor circuit apparatus described herein should only be limited in light of the claims that follow when taken in conjunction with the above description and accompanying drawings.

What is claimed is:

1. A semiconductor circuit apparatus comprising:
first and second ranks; and
a rank control block shared by the first and second ranks and configured to provide a column-related command and an address to one of the first and second ranks in response to a chip select signal for selecting the first or second rank.

2. The semiconductor circuit apparatus according to claim 1, wherein the rank control block latches the address at the same time when the column-related command is received, and provides the latched address to one of the first rank and the second rank corresponding to the chip select signal at a predetermined timing.

3. The semiconductor circuit apparatus according to claim 2, wherein the rank control block comprises:
a command reception unit configured to receive the column-related command and provide a column-related activation signal for each rank in response to the chip select signal;
a column command control unit configured to provide a first rank column-related signal and a second rank column-related signal in accordance with the column-related activation signal for each rank in response to the chip select signal, and provide a read combined information signal or write combined information signal defining whether the column-related command is a read command signal or write command signal, regardless of rank information; and
an address control unit configured to latch the address in response to the read combined information signal and the write combined information signal, respectively, delay the address by applying a write latency in a write mode, and then provide the delayed address to a corresponding rank.

4. The semiconductor circuit apparatus according to claim 3, wherein the address control unit comprises:
first and second address latch sections configured to latch the address in the read mode and the write mode, respectively;
a shifter register section configured to delay an output of the second address latch section by the write latency in the write mode; and
first and second address supply sections configured to receive output signals from the first address latch section and the shifter register and provide the received signals to a corresponding activated rank.

5. A semiconductor circuit apparatus comprising:
first and second ranks;
a command control unit configured to provide a column-related activation signal for each rank and read and write information signals of the corresponding rank in response to an chip signal for selecting the first or second rank; and
an address control unit configured to latch the address in response to read and write combined information signals irrelevant to rank information.

6. The semiconductor circuit apparatus according to claim 5, wherein the command control unit provides write information signal of the corresponding rank in a write mode, the write information signal being delayed by more than a clock period obtained by summing a write latency and a burst length in comparison with the column-related activation signal for each rank.

7. The semiconductor circuit apparatus according to claim 5, wherein the address control unit delays the latched address by a predetermined write latency in response to the write information signal of the corresponding rank, and provides the delayed address to the corresponding rank.

8. The semiconductor circuit apparatus according to claim 7, wherein the address control unit comprises:
first and second address latch sections configured to latch the address in the read mode and the write mode, respectively;
a shift register section configured to delay an output of the second address latch section by the write latency in the write mode; and
first and second address supply sections configured to receive output signals from the first address latch and the shift register section, and provide the received signals to the corresponding activated ranks, respectively.

9. The semiconductor circuit apparatus according to claim 8, wherein the first address latch section latches the address to provide as a read address in the read mode, and the second address latch section latches the address to provide as a write address in the write mode.

10. The semiconductor circuit apparatus according to claim 8, wherein the shift register section synchronizes the write address with a clock signal to delay the write address by the write latency, and provides as a delayed write address.

11. The semiconductor circuit apparatus according to claim 10, wherein the shift register section includes a plurality of transmission sections, each of which includes a transmission gate and a latch unit.

12. A semiconductor circuit apparatus comprising:
first and second ranks; and
a rank control block shared by the first and second ranks and configured to receive first and second chip select signals corresponding to the first or second ranks, respectively and configured to provide read or write column-related commands and to provide an address to the first and second ranks corresponding to the first and second chip select signals.

13. The semiconductor circuit apparatus according to claim 12, wherein the rank control block latches the address when anyone of the write column-related commands is received, and provides after a predetermined time the latched address to the first and second ranks corresponding to the first and second chip select signals.

14. The semiconductor circuit apparatus according to claim 13, wherein the rank control block comprises a command control block and an address control block, the command control block comprises:
a command reception unit configured to receive anyone of the read or write column-related commands and to receive anyone of the chip select signals and configured to provide a read rank signal or a write rank signal to first and second ranks corresponding to the chip select signal and which correspond to the read or write column-related commands; and
a column command control unit configured to receive the read rank signal or the write rank signals and to receive the read or write column-related commands, and configured to provide a read or write combined information signal and to provide a read or write rank column-related activation signal corresponding to the received chip select signal and corresponding to the received read or write column-related commands; and
the address control block comprises an address control unit configured to latch the address in response to the read or write combined information signal, delay the address, and subsequently provide the delayed address to the first and second ranks corresponding to the chip select signal and corresponding to the read or write combined information signal.

15. The semiconductor circuit apparatus according to claim 14, wherein the address control unit comprises:
a first latch section configured to latch the address in response to the read combined information signal to latch the address in a read mode;
a second latch section configured to latch the address in response to the write combined information signal to latch the address when in a write mode;
a shifter register section configured to delay an output of the second address latch section when in the write mode; and
first and second address supply sections configured to receive output signals from the first address latch section and from the shifter register section and to provide first or second rank address signals to corresponding first and second ranks.
